(19) United States
(12) Patent Application Publication
(10) Pub. No.: US 2015/0162111 A1
(43) Pub. Date: Jun. 11, 2015

(54) Transparent Conductive Films and Methods for Forming the Same

(71) Applicant: Intermolecular, Inc., San Jose, CA (US)

(72) Inventors: Guowen Ding, San Jose, CA (US); Minh Huu Le, San Jose, CA (US)

(73) Assignee: Intermolecular, Inc., San Jose, CA (US)

(21) Appl. No.: 14/101,668

(22) Filed: Dec. 10, 2013

(51) Int. Cl. H01B 5/14; C23C 14/14; H01B 1/02

(52) U.S. Cl. CPC H01B 5/14; H01B 1/02; C23C 14/14

(57) ABSTRACT

Embodiments provided herein describe transparent conductive films and methods for forming transparent conductive films. A transparent substrate is provided. A first layer is formed above the transparent substrate. The first layer includes nickel. A second layer is formed above the first layer. The second layer includes silver and palladium. A third layer is formed above the second layer. The third layer comprises nickel.

### TECHNICAL FIELD

The present invention relates to conductive films. More particularly, this invention relates to transparent conductive films and method for forming transparent conductive films.

### BACKGROUND OF THE INVENTION

Transparent conductive films are used in a wide range of devices, many of which include a touch screen, such as digital wrist watches, monitors, laptop computers, portable electronic systems (e.g., MP3 players), etc. Transparent conductive films may also be used in various types of panels, such as solar panels, electrochromic panels, and low-e windows.

Transparent conductive films are often made of a stack of thin layers of various materials. For example, many current transparent conductive films include layers of indium-tin oxide (ITO) and a dielectric material, such as silicon oxide (e.g., a layer of silicon oxide formed between two layers of ITO). ITO-based transparent conductive films perform well with respect to transparency (or transmittance) and conductivity, as they typically achieve 85% transparency with a resistance of 20 ohms, perhaps as low as 10-15 ohms. Additionally, these films provide excellent durability, as they typically exhibit resistance changes of less than 10% after undergoing conventional acid/base solvent testing. However, ITO is very expensive to manufacture, particularly when the lower resistance (e.g., 10-15 ohms) is desired.

Silver has been contemplated as a replacement for ITO in transparent conductive films, as it is easily capable of providing suitable transparency and resistance. However, silver usually provides very poor durability, as it's performance will decay very quickly if exposed to the atmosphere, and it's resistance significantly after undergoing acid/base testing.

### BRIEF DESCRIPTION OF THE DRAWINGS

To facilitate understanding, identical reference numerals have been used, where possible, to designate identical elements that are common to the figures. The drawings are not to scale and the relative dimensions of various elements in the drawings are depicted schematically and not necessarily to scale.

The techniques of the present invention can readily be understood by considering the following detailed description in conjunction with the accompanying drawings, in which:

FIG. 1 is a cross-sectional side view of a coated article according to some embodiments.

FIG. 2 is a table of data related to various performance characteristics for coated articles according to some embodiments.

FIG. 3 is a simplified cross-sectional diagram illustrating a physical vapor deposition (PVD) tool according to some embodiments.

FIG. 4 is a flow chart illustrating a method for forming a transparent conductive film, or a coated article, according to some embodiments.

### DETAILED DESCRIPTION

A detailed description of one or more embodiments is provided below along with accompanying figures. The detailed description is provided in connection with such embodiments, but is not limited to any particular example. The scope is limited only by the claims, and numerous alternatives, modifications, and equivalents are encompassed. Numerous specific details are set forth in the following description in order to provide a thorough understanding. These details are provided for the purpose of example and the described techniques may be practiced according to the claims without some or all of these specific details. For the purpose of clarity, technical material that is known in the technical fields related to the embodiments has not been described in detail to avoid unnecessarily obscuring the description.

The term “horizontal” as used herein will be understood to be defined as a plane parallel to the plane or surface of the substrate, regardless of the orientation of the substrate. The term “vertical” will refer to a direction perpendicular to the horizontal as previously defined. Terms such as “above”, “below”, “bottom”, “top”, “side” (e.g. sidewall), “higher”, “lower”, “upper”, “over”, and “under”, are defined with respect to the horizontal plane. The term “on” means there is direct contact between the elements. The term “above” will allow for intervening elements.

Some embodiments described herein provide improved transparent conductive films, for use in various devices, such as touch screen devices, solar panels, electrochromic panels, etc., and methods for forming such films. In some embodiments, a transparent, conductive film stack is provided which utilizes silver and provides suitable durability. This is accomplished by using, for example, a silver-palladium alloy along with barrier layers to protect the silver-palladium layer.

In some embodiments, a silver-palladium alloy layer is formed above a transparent substrate, such as glass or a plastic. The barrier layers may be formed on opposing sides of the silver-palladium alloy layer. In some embodiments, the barrier layers include nickel. The barrier layers may also include niobium, titanium, chromium, molybdenum, or a combination thereof (e.g., nickel alloys, such as nickel-niobium, nickel-titanium, nickel-chromium, and nickel-molybdenum).

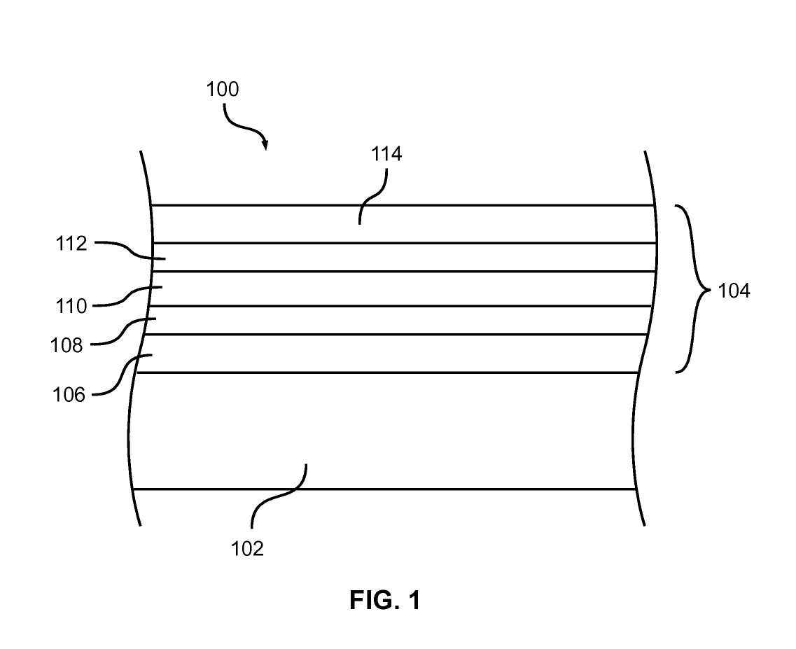

FIG. 1 illustrates a coated article 100 according to some embodiments. The coated article 100 includes a transparent substrate 102 and a transparent conductive film (or coating or stack) 104 formed above the transparent substrate 102. In some embodiments, the transparent substrate 102 is made of glass. However, in some embodiments, the transparent substrate 102 may be made of plastic or a transparent polymer, such as polyethylene terephthalate (PET), poly(methyl methacrylate) (PMMA), polycarbonate (PC), and polyimide (PI). It should be noted that in some embodiments the transparent substrate 102 may be flexible (e.g., made of a flexible plastic). The transparent substrate 102 has a thickness of, for example, between about 1 and about 10 millimeters (mm). In a testing environment, the transparent substrate 102 may be round with a diameter of, for example, about 200 or about 300 mm. However, in a manufacturing environment, the transparent substrate 102 may be square or rectangular and significantly larger (e.g., about 0.5- about 4 meters (m) across).

The transparent conductive film 104 includes a first (or lower) dielectric layer 106, a first barrier layer 108, a conductive layer 110, a second (or upper) barrier layer 112, and a second dielectric layer 114. Exemplary details as to the functionality provided by each of the layers 106-114 are provided below.

The various layers in the transparent conductive film 104 may be formed sequentially (i.e., from bottom to top) above the transparent substrate 102 using, for example, a physical vapor deposition (PVD) and/or reactive sputtering processing tool. In some embodiments, the transparent conductive film 104 is formed above the entire substrate 102. However, in some embodiments, the transparent conductive film 104 may only be formed above isolated portions of the transparent substrate 102. Although the layers may be described as being formed “above” the previous layer (or the substrate), it should be understood that in some embodiments, each layer is formed directly on (and adjacent to) the previously provided/formed component (e.g., layer). In some embodiments, additional layers may be included between the layers, and other processing steps may also be performed between the formation of various layers.

The first dielectric layer 106 is formed above the transparent substrate 102. The first dielectric layer 106 may include (or be made of) a dielectric material, such as a nitride. In some embodiments, the first dielectric layer 106 is made of silicon nitride. The first dielectric layer 106 may have a thickness of, for example, between about 20 nanometers (nm) and about 40 nm. The first dielectric layer 106 may be used to tune the optical properties (e.g., color, transmittance, etc.) of the coated article 100 as a whole, as well as to protect the other layers in the transparent conductive film 104 from material which may diffuse from the transparent substrate 102.

The first barrier layer 108 is formed above the first dielectric layer 106. The first barrier layer 108 may include nickel. In some embodiments, the first barrier layer 108 includes nickel and at least one of niobium, titanium, chromium, molybdenum, or a combination thereof. For example, the first barrier layer 108 may be made of a nickel alloy, such as nickel-niobium, nickel-titanium, nickel-chromium, and nickel-molybdenum. The first barrier layer 108 may have a thickness of, for example, between about 2 nm and about 5 nm. The first barrier layer 108 is used to, for example, prevent any interaction of the material of the conductive layer 110 with the materials of the first dielectric layer 106 and the transparent substrate 102, which may result in undesirable optical characteristics of the coated article 100, such as poor color performance.

The conductive layer 110 is formed above the first barrier layer 108. The conductive layer 110 may include silver. In some embodiments, the conductive layer 110 includes silver and palladium. The conductive layer 110 may be made of silver-palladium alloy having, for example, between about 1% and about 5% palladium by weight. The conductive layer 110 may have a thickness of, for example, between about 5 nm and about 15 nm, such as about 10 nm. The conductive layer 110 may serve as the primary electrical conductor of the transparent conductive film 104. As will be appreciated by one skilled in the art, when formed to the thicknesses previously described, the conductive layer 110 remains transparent, or substantially transparent.

The second barrier layer 112 is formed above the conductive layer 110. The second barrier layer 112 may include nickel. In some embodiments, the second barrier layer 112 includes nickel and at least one of niobium, titanium, chromium, molybdenum, or a combination thereof. For example, the second barrier layer 112 may be made of a nickel alloy, such as nickel-niobium, nickel-titanium, nickel-chromium, and nickel-molybdenum. In some embodiments, the second barrier layer 112 is made of the same material(s) as the first barrier layer 108. The second barrier layer 112 may have a thickness of, for example, between about 2 nm and about 5 nm (i.e., similar to the first barrier layer 108). The second barrier layer 112 is used to, for example, prevent any interaction of the material of the conductive layer 110 with the material(s) of the second dielectric layer 114, which may result in undesirable optical characteristics of the coated article 100, such as poor color performance.

The second dielectric layer 114 is formed above the second barrier layer 112. The second dielectric layer 114 may include (or be made of) a dielectric material, such as a nitride. In some embodiments, the first dielectric layer 106 is made of silicon nitride. That is, the second dielectric layer 114 may be made of the same material(s) as the first dielectric layer 106. The second dielectric layer 114 may have a thickness of, for example, between about 20 nm and about 40 nm (i.e., similar to the first dielectric layer 106). The second dielectric layer 114 may be used to tune the optical properties (e.g., color, transmittance, etc.) of the coated article 100 as a whole, as well as to protect the other layers in the transparent conductive film 104 from material which may diffuse from the transparent substrate 102. Additionally, the second dielectric layer 114 may protect the other layers in the transparent conductive film 104 from being damaged (e.g., by being scratched).

One skilled in the art will appreciate that the embodiment depicted in FIG. 1 includes only one (primary) conductive layer (e.g., silver-palladium). However, in some embodiments, the transparent conductive film 104 is formed with multiple conductive layers 110 (e.g., two or more conductive layers 110). In such embodiments, each of the conductive layers 110 may be formed between two barrier layers (e.g., barrier layers 108 and 112) such that the transparent conductive film 104 includes a series of layers alternating between, for example, a nickel alloy (i.e., for the barrier layers) and silver-palladium (i.e., for the conductive layers). However, in some embodiments, such transparent conductive films may only include two dielectric layers (e.g., dielectric layers 106 and 114) at the “bottom” and “top” of the stack of layers.

It should be noted that depending on the materials used, some of the layers of the transparent conductive film 104 may have some materials in common. For example, in some embodiments, the dielectric layers 106 and 114 are made of the same material (e.g., silicon nitride). Similarly, in some embodiments, the barrier layers 108 and 112 are made of the same material (e.g., nickel-niobium alloy).

Although not shown, it should also be understood that the coated article 100 may be used, or installed, in any system or device in which the use of a coated article with a transparent conductive film is desired, such digital wrist watches, monitors, laptop computers, portable electronic systems, etc. with touch screen devices, as well as solar panels, electrochromic panels, etc.

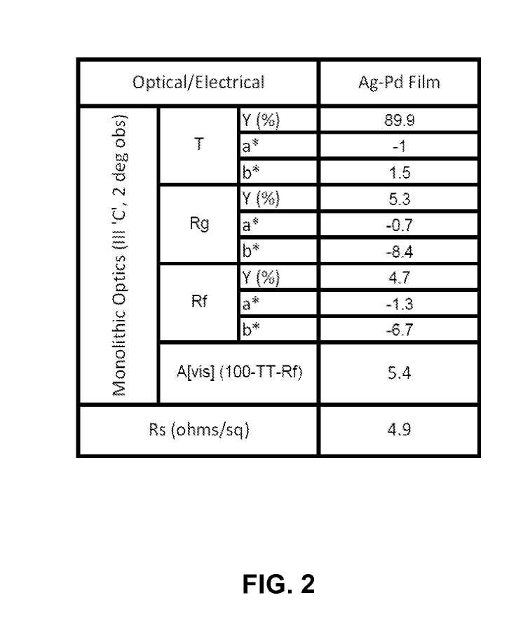

Various characteristics of the coated articles described herein are shown in the table depicted in FIG. 2. Data are presented for monolithic coated articles (e.g., Monolithic Optics). Due to the distribution of cones in the eye, the color observance may depend on the observer's field of view. Standard (colorimetric) observer is used, which was taken to be the chromatic response of the average human viewing through a 2 degree angle, due to the belief that the color-sensitive cones reside within a 2 degree arc of the field of view. Thus, the measurements are shown for the 2 degree Standard Observer.

The various characteristics listed in FIG. 2 will be understood and appreciated by one skilled in the art. For example, intensity of reflected visible wavelength light, (e.g., “reflectance”) is defined for glass side “g” or for film side “f”. Intensity from glass side reflectance, (e.g., R_{g}Y), shows light intensity measured from the side of the glass substrate opposite the side of the coated layers. Intensity from film side reflectance, (e.g., R_{f}Y), shows light intensity measured from the side of the glass substrate on which the coated layers are formed. Transmittance, (e.g., TY), shows light intensity measured for the transmitted light.

Emissivity (E) is a characteristic of both absorption and reflectance of light at given wavelengths. It can usually represented as a complement of the reflectance by the film side, (e.g., E=1−R_{f}). For architectural purposes, emissivity values can be important in the far range of the infrared spectrum, (e.g., about 2,500-40,000 nm). Thus, the emissivity value reported here includes normal emissivity (EN), as measured in the far range of the infrared spectrum. Haze is a percentage of light that deviates from the incident beam greater than 2.5 degrees on the average.

Of particular interest in FIG. 2 is that the coated articles described herein, at least in some embodiments, demonstrated a transmittance (TY) of 89.9 and a sheet resistance (Rₛ) of 4.9 ohms/square. Both of these characteristics are suitable for many applications of transparent conduct films, as current typical indium-tin oxide (ITO) films have a transmittance of about 85%, and a sheet resistance of about 20 ohms/square, perhaps as low as 10-15 ohms/square (which is considerably higher than the transparent conductive films described herein).

Additionally, when compared to conventional transparent conductive films using pure silver, the transparent conductive films described herein demonstrated improved durability. For example, when exposed to a 35% hydrochloric acid solution at 65° C. for 5 minutes, the resistance only increased about 5%, and when exposed to a 20% sodium hydroxide solution at 65° C. for 5 minutes, the resistance only increased about 4%.

The transparent conductive films described herein may also be significantly thinner than conventional ITO-based films. For example, in some embodiments, the transparent conductive films described herein may have a total thickness of, for example, between about 45 nm and about 105 nm, which may be less than half of the thickness of conventional ITO-based films with 20 ohms of resistance, which are usually about 200 nm thick. Moreover, the thickness of the transparent conductive films described herein may be even thinner when compared to conventional ITO-based films with 10-15 ohms of resistance, which are usually 300-400 nm thick (which typically include more than two ITO layers). Further, although palladium may be rather expensive, because the silver-palladium layer used in some embodiments is so thin (e.g., about 10 nm), the manufacturing costs are lower than that of ITO.

As an additional benefit, in some embodiments, manufacturing costs may be minimized because many of the layers in the transparent conductive films described herein utilize materials used in the other layers. As a result, the total number of targets that are required to form the transparent conductive films may be reduced.

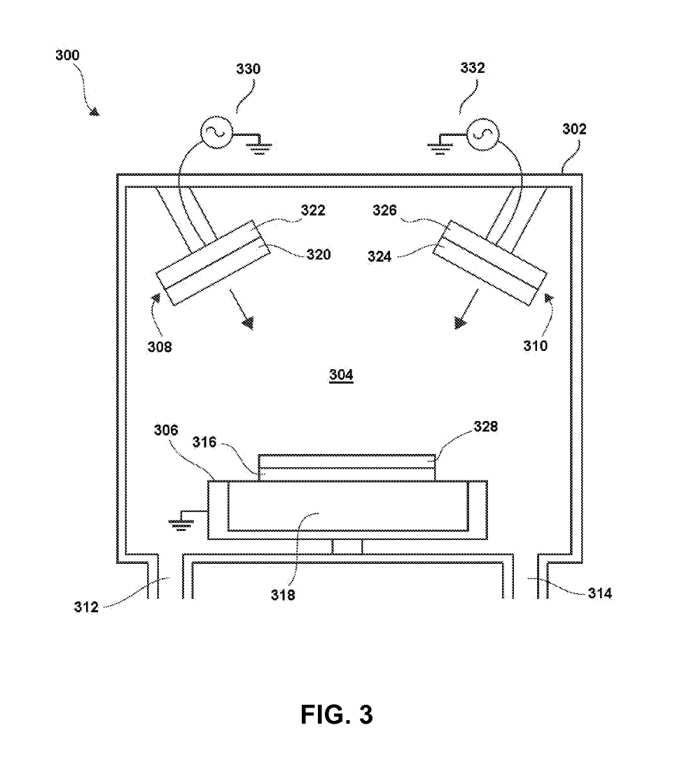

FIG. 3 provides a simplified illustration of a physical vapor deposition (PVD) tool (and/or system) 300 which may be used, in some embodiments, to form a transparent conductive film, or a coated article, such as described above. The PVD tool 300 shown in FIG. 3 includes a housing 302 that defines, or encloses, a processing chamber 304, a substrate support 306, a first target assembly 308, and a second target assembly 310.

The housing 302 includes a gas inlet 312 and a gas outlet 314 near a lower region thereof on opposing sides of the substrate support 306. The substrate support 306 is positioned near the lower region of the housing 302 and in configured to support a substrate 316. The substrate 316 may be a round substrate having a diameter of, for example, about 200 mm or about 300 mm. In other embodiments (such as in a manufacturing environment), the substrate 316 may have other shapes, such as square or rectangular, and may be significantly larger (e.g., about 0.5 m to about 4 m across). The substrate support 306 includes a support electrode 318 and is held at ground potential during processing, as indicated.

The first and second target assemblies (or process heads) 308 and 310 are suspended from an upper region of the housing 302 within the processing chamber 304. The first target assembly 308 includes a first target 320 and a first target electrode 322, and the second target assembly 310 includes a second target 324 and a second target electrode 326. As shown, the first target 320 and the second target 324 are oriented or directed towards the substrate 316. As is commonly understood, the first target 320 and the second target 324 include one or more materials that are to be used to deposit a layer of material 328 on the upper surface of the substrate 316.

The materials used in the targets 320 and 324 may, for example, silver, palladium, nickel, niobium, titanium, chromium, molybdenum, zinc, tin, silicon, aluminum, manganese, zirconium, hathium, copper, or any combination thereof (i.e., a single target may be made of an alloy of several metals, such as silver-palladium). Additionally, the materials used in the targets may include oxygen, nitrogen, or a combination of oxygen and nitrogen in order to form oxides, nitrides, and oxynitrides. Additionally, although only two targets 320 and 324 are shown, additional targets may be used.

The PVD tool 300 also includes a first power supply 330 coupled to the first target electrode 322 and a second power supply 332 coupled to the second target electrode 324. As is commonly understood, in some embodiments, the power supplies 330 and 332 pulse direct current (DC) power to the respective electrodes, causing material to be, at least in some embodiments, simultaneously sputtered (i.e., co-sputtered) from the first and second targets 320 and 324. In some embodiments, the power is alternating current (AC) to assist in directing the ejected material towards the substrate 316.

During sputtering, inert gases (or a plasma species), such as argon or krypton, may be introduced into the processing chamber 304 through the gas inlet 312, while a vacuum is applied to the gas outlet 314. The inert gas(es) may be used to impact the targets 320 and 324 and eject material therefrom, as is commonly understood. In embodiments in which reactive sputtering is used, reactive gases, such as oxygen and/or nitrogen, may also be introduced, which interact with particles ejected from the targets (i.e., to form oxides, nitrides, and/or oxynitrides).

Although not shown in FIG. 3, the PVD tool 300 may also include a control system having, for example, a processor and a memory, which is in operable communication with the other components shown in FIG. 3 and configured to control the operation thereof in order to perform the methods described herein.

Although the PVD tool 300 shown in FIG. 3 includes a stationary substrate support 306, it should be understood that in a manufacturing environment, the substrate 316 may be in motion (e.g., an in-line configuration) during the formation of various layers described herein.

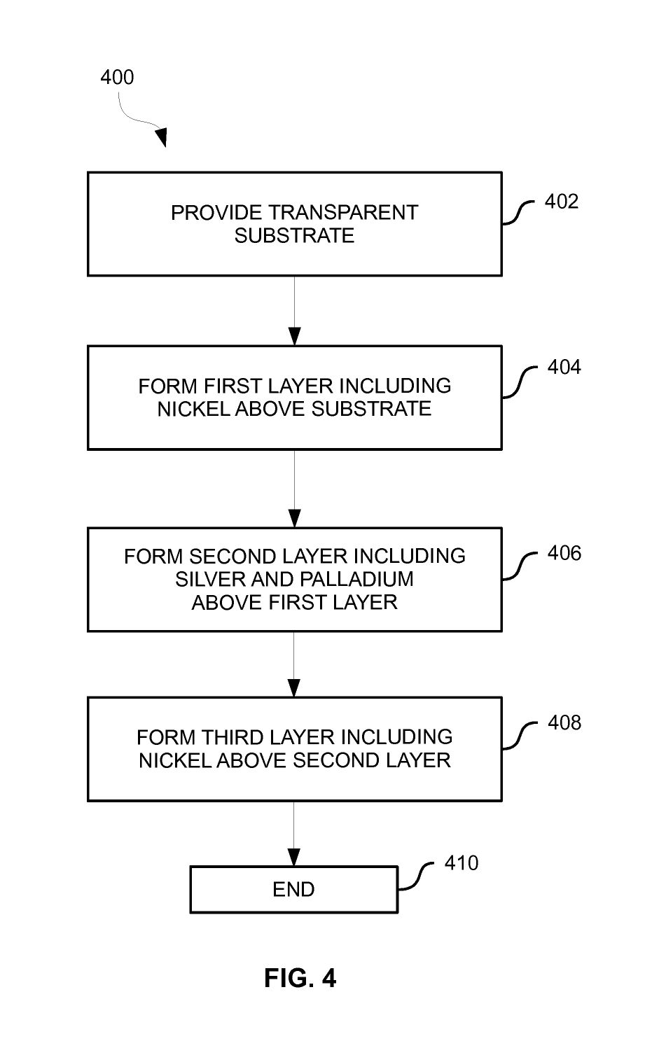

FIG. 4 is a flow chart illustrating a method 400 for forming a transparent conductive film, or a coated article, according to some embodiments. The method 400 begins at block 402 by providing a transparent substrate. As described above, the transparent substrate may be made of, for example, glass, a plastic, or a polymer. In some embodiments, the transparent substrate is flexible.

At block 404, a first layer, including nickel, is formed above the transparent substrate. In some embodiments, the first layer includes nickel and at least one of niobium, titanium, chromium, molybdenum, or a combination thereof. For example, the first layer may be made of a nickel alloy, such as nickel-niobium, nickel-titanium, nickel-chromium, and nickel-molybdenum. The first layer may have a thickness of, for example, between about 2 nm and about 5 nm. In some embodiments, the first layer is a barrier layer.

At block 406, a second layer, including silver and palladium, is formed above the first layer. The second layer may be made of silver-palladium alloy. The second layer may have a thickness of, for example, between about 5 nm and about 15 nm, such as about 10 nm. In some embodiments, the second layer is a conductive layer.

At block 408, a third layer, including nickel, is formed above the second layer. In some embodiments, the third layer includes nickel and at least one of niobium, titanium, chromium, molybdenum, or a combination thereof. For example, the third layer may be made of a nickel alloy, such as nickel-niobium, nickel-titanium, nickel-chromium, and nickel-molybdenum. The third layer may have a thickness of, for example, between about 2 nm and about 5 nm. In some embodiments, the third layer is a barrier layer and may be made of the same material(s) as the first layer.

Although not shown in FIG. 4, the method 400 may also include forming a fourth layer between the first layer and the transparent substrate and a fifth layer above the third layer. The fourth and fifth layers may be made of a dielectric material, such as silicon nitride. At block 410, the method 400 ends.

Thus, in some embodiments, a method for forming a transparent conductive film is provided. A transparent substrate is provided. A first layer is formed above the transparent substrate. The first layer includes nickel. A second layer is formed above the first layer. The second layer includes silver and palladium. A third layer is formed above the second layer. The third layer comprises nickel.

In some embodiments, a method for forming a transparent conductive film is provided. A transparent substrate is provided. A first dielectric layer is formed above the transparent substrate. A first barrier layer is formed above the first dielectric layer. The first barrier layer includes nickel. A conductive layer is formed above the first barrier layer. The conductive layer includes silver and palladium. A second barrier layer is formed above the conductive layer. The second barrier layer includes nickel. A second dielectric layer is formed above the second barrier layer.

In some embodiments, a coated article is provided. The coated article includes a transparent substrate. A first barrier layer is formed above the transparent substrate. The first layer includes nickel. A conductive layer is formed above the first barrier layer. The conductive layer includes silver and palladium. A second barrier layer is formed above the conductive layer. The third layer includes nickel.

Although the foregoing examples have been described in some detail for purposes of clarity of understanding, the invention is not limited to the details provided. There are many alternative ways of implementing the invention. The disclosed examples are illustrative and not restrictive.

What is claimed:

1. A method for forming a transparent conductive film, the method comprising:
providing a transparent substrate;
forming a first layer above the transparent substrate, wherein the first layer comprises nickel;
forming a second layer above the first layer, wherein the second layer comprises silver and palladium; and
forming a third layer above the second layer, wherein the third layer comprises nickel.

2. The method of claim 1, wherein the second layer comprises silver-palladium alloy.

3. The method of claim 2, wherein the silver-palladium alloy comprises between about 1% and about 5% palladium by weight.

4. The method of claim 1, wherein the first layer further comprises one of niobium, titanium, chromium, molybdenum, or a combination thereof.

5. The method of claim 4, wherein the third layer further comprises one of niobium, titanium, chromium, molybdenum, or a combination thereof.

6. The method of claim 5, wherein each of the first layer and the third layer comprises one of nickel-niobium, nickel-titanium, nickel-chromium, nickel-molybdenum, or a combination thereof.

7. The method of claim 1, wherein the second layer has a thickness of between about 5 nanometers (nm) and about 15 nm.

8. The method of claim 6, wherein each of the first layer and the third layer has a thickness of between about 2 nm and about 5 nm.

9. The method of claim 1, further comprising:
forming a fourth layer above the transparent substrate, wherein fourth layer comprises a dielectric material and the first layer is formed above the fourth layer; and
forming a fifth layer above the third layer, wherein the fifth layer comprises a dielectric material.

10. The method of claim 8, wherein each of the fourth layer and the fifth layer comprises silicon nitride and each has a thickness of between about 20 nm and about 40 nm.

11. A method for forming a transparent conductive film, the method comprising:
providing a transparent substrate;
forming a first dielectric layer above the transparent substrate;
forming a first barrier layer above the first dielectric layer, wherein the first barrier layer comprises nickel;
forming a conductive layer above the first barrier layer, wherein the conductive layer comprises silver and palladium;
forming a second barrier layer above the conductive layer, wherein the second barrier layer comprises nickel; and
forming a second dielectric layer above the second barrier layer.

12. The method of claim 11, wherein the conductive layer comprises silver-palladium alloy, the silver-palladium allow comprising between about 1% and about 5% palladium by weight.

13. The method of claim 12, wherein each of the first barrier layer and the second barrier layer comprises one of nickel-niobium, nickel-titanium, nickel-chromium, nickel-molybdenum, or a combination thereof.

14. The method of claim 13, wherein each of the first dielectric layer and the second dielectric layer comprises silicon nitride.

15. The method of claim 14, wherein the conductive layer has a thickness of between about 5 nm and about 15 nm, and each of the first barrier layer and the second barrier layer has a thickness of between about 2 nm and about 5 nm.

16. A coated article comprising:
a transparent substrate;
a first barrier layer formed above the transparent substrate, wherein the first barrier layer comprises nickel;
a conductive layer formed above the first barrier layer, wherein the conductive layer comprises silver and palladium; and
a second barrier layer above the conductive layer, wherein the second barrier layer comprises nickel.

17. The coated article of claim 16, wherein the conductive layer comprises silver-palladium alloy, the silver-palladium alloy comprising between about 1% and about 5% palladium by weight.

18. The coated article of claim 17, wherein each of the first barrier layer and the second barrier layer comprises one of nickel-niobium, nickel-titanium, nickel-chromium, nickel-molybdenum, or a combination thereof.

19. The coated article of claim 18, wherein the conductive layer has a thickness of between about 5 nm and about 15 nm, and each of the first barrier layer and the second barrier layer has a thickness of between about 2 nm and about 5 nm.

20. The coated article of claim 19, further comprising:
a first dielectric layer formed between the transparent substrate and the first barrier layer; and
a second dielectric layer formed above the second barrier layer,
wherein each of the first dielectric layer and the second dielectric layer comprises silicon nitride and has a thickness of between about 20 nm and about 40 nm.
